(19) United States
(12) Patent Application Publication
(10) Pub. No.: US 2025/0101597 A1
(43) Pub. Date: Mar. 27, 2025

(54) COMPOSITE STRUCTURE AND SEMICONDUCTOR MANUFACTURING APPARATUS INCLUDING COMPOSITE STRUCTURE

(71) Applicant: TOTO LTD., KITAKYUSHU-SHI, FUKUOKA (JP)

(72) Inventors: Hiroaki ASHIZAWA, KITAKYUSHU-SHI, FUKUOKA (JP); Ryoto TAKIZAWA, KITAKYUSHU-SHI, FUKUOKA (JP)

(21) Appl. No.: 18/730,081

(22) PCT Filed: Feb. 13, 2023
(86) PCT No.: PCT/JP2023/004709

§ 371 Date: Jul. 18, 2024

(30) Foreign Application Priority Data
Feb. 26, 2022 (JP) 2022-028737
Feb. 26, 2022 (JP) 2022-028738

(51) Int. Cl. C23C 24/04; H01J 37/32

(52) U.S. Cl. CPC C23C 24/04; H01J 37/32495

(57) ABSTRACT

Disclosed is a composite structure having low-particle generation usable for a member for a semiconductor manufacturing apparatus and also the semiconductor manufacturing apparatus. The composite structure including a base material and a structure that is provided on the base material wherein the structure comprises Y₂O₃—ZrO₂ solid solution (YZrO) as a main component, and lattice constant of the YZrO is 5.252 Å or greater or has an indentation hardness of more than 12 GPa. has low-particle generation and is suitably used as a member for a semiconductor apparatus.

### TECHNICAL FIELD

The present invention relates to a composite structure which is excellent in an anti-particle property (low-particle generation property) to be suitably used as a member for a semiconductor manufacturing apparatus, and a semiconductor manufacturing apparatus including the same.

### BACKGROUND ART

There has been known a technology with which a substrate is imparted with a function by means of coating a surface thereof with a ceramics. For instance, as a member for a semiconductor manufacturing apparatus used under a plasma exposure environment, a member having highly plasma resistant coating formed on its surface has been used. As the coating, for example, oxide-based ceramics such as alumina (Al₂O₃) or yttria (Y₂O₃), or fluorides such as yttrium fluoride (YF₃) or yttrium oxyfluoride (YOF) is used.

Y₂O₃ based ceramics are excellent in plasma resistance, and the material combining it with ZrO₂ to improve its mechanical strength is known as Y₂O₃—ZrO₂ (PTL 1 and PTL2). In these prior patents, the content of Y₂O₃ is set to be 40 mol % or more (PTL 1) and 7 to 17 mol % (PTL 2).

Furthermore, while there are prior art technologies for producing Y₂O₃—ZrO₂ materials by aerosol deposition methods (AD methods) (PTL 3 and PTL4), none of them disclose the plasma resistance or particle resistance of the materials, and the Y₂O₃ content is 14 mol % or less (PTL 3) and 15 wt % (mol % equivalent value: 8.8 mol %) (PTL 4).

Due to miniaturization of semiconductors, a higher level of low-particle generation has been required for various members in the semiconductor manufacturing apparatus and the materials that can meet this requirement remain in demand.

### CITATION LIST

PLT 1: JP 2008-239385A
PLT 2: JP 2022-37666A
PLT 3: JP 2011-84787A
PLT 4: JP 2017-514991A

### SUMMARY OF INVENTION

### Technical Problem

We have now found that by making the lattice constant of a Y₂O₃—ZrO₂ solid solution (YZrO) larger than the value that YZrO normally has, fluorination can be suppressed in a fluorine plasma environment. Furthermore, we also have found that by controlling the indentation hardness of a Y₂O₃—ZrO₂ solid solution (YZrO), fluorination can be suppressed in a fluorine plasma environment. The present invention is based on these findings.

Thus, an object of the present invention is to provide a composite structure with excellent low-particle generation. A further object is to enable such a composite structure to be used as a member of a semiconductor manufacturing apparatus and to provide a semiconductor manufacturing apparatus using the same.

A composite structure according to one embodiment of the present invention comprising: a base material; and a structure provided on the base material and has a surface, wherein the structure comprises Y₂O₃—ZrO₂ solid solution (YZrO) as a main component, and a lattice constant of the YZrO is 5.252 or greater.

A composite structure according to one embodiment of the present invention comprising: a base material; and a structure provided on the base material and has a surface, wherein the structure comprises Y₂O₃—ZrO₂ solid solution (YZrO) as a main component, and has an indentation hardness of more than 12 GPa.

The composite structure according to the present invention can be used in an environment requiring low-particle generation.

A semiconductor manufacturing apparatus according to the present invention includes the composite structure according to the present invention described above.

### BRIEF DESCRIPTION OF DRAWINGS

FIG. 1 is a schematic-cross sectional view of a member including a structure of the present invention. The composite structure 10 includes a structure 20 provided on a base material 15, and the structure 20 has a surface 20a that is exposed to the plasma environment . . . .

FIG. 2 is a graph showing the relationship between the lattice constant and the Y₂O₃ content of the structure according to the present invention.

FIG. 3 is a graph showing the relationship between indentation hardness and Y₂O₃ content of structures according to the present invention.

FIG. 4 is SEM images of the surface of the structures after Standard Plasma Tests 1 to 3.

### DESCRIPTION OF EMBODIMENTS

### Composite Structure

A basic structure of a composite structure according to the present invention will be described with reference to FIG. 1. FIG. 1 is a schematic cross-sectional view of a composite structure 10 according to the present invention. The composite structure 10 includes a structure 20 provided on a base material 15, and the structure 20 has a surface 20a.

The structure 20 of the composite structure of the present invention is what is known as a ceramic coating. With the ceramic coating provided, the base material 15 can have various physical properties/characteristics. The structure (or the ceramic structure) and the ceramic coating are synonymously used herein unless noted otherwise.

For example, the composite structure 10 is provided inside a chamber of a semiconductor manufacturing apparatus including the chamber. The composite structure 10 can constitute inner wall of the chamber. Fluorine based gas, such as SF based gas or CF based gas, is introduced into the chamber to generate plasma, whereby the surface 20a of the structure 20 is exposed to the plasma environment. Thus, low-particle generation is required for the structure 20 at the surface of the composite structure 10. The composite structure of the present invention may be used as a member mounted to a part other than the inside of the chamber. In this specification, the semiconductor manufacturing apparatus for which the composite structure according to the present invention is used is meant to include any semiconductor manufacturing apparatus (semiconductor processing apparatus) executing processing such as annealing, etching, sputtering, or CVD.

### Base Material

In the present invention, the base material 15, which is not particularly limited as long as it is used for its purpose, is configured to include alumina, quartz, anodized aluminum (alumite), metal, or glass, and is preferably configured to include alumina. According to a preferred embodiment of the present invention, an arithmetic average roughness Ra (JISB0601: 2001) of a surface of the base material 15 on which the structure 20 is formed is, for example, less than 5 micrometers (μm), preferably less than 1 μm, and is more preferably less than 0.5 μm.

### Structure

The structure of the present invention includes Y₂O₃—ZrO₂ solid solution (YZrO) as a main component, and the lattice constant of YZIO is 5.252 Å (angstrom) or more, preferably 5.270 Å. In the present invention, the structure is in the solid solution form.

In the present invention, the main component of the structure is a compound that is contained in the structure 20 by an amount relatively larger than those of other compounds, as identified by quantitative or semi-quantitative analysis with X-ray diffraction (XRD). For example, the main component is a compound of the largest amount included in the structure. The ratio of the main component in the structure, which is volume ratio or mass ratio, is 50% or more. Furthermore, the ratio of the main component is preferably more than 70%, and is also preferably more than 90%. The ratio of the main component may even be 100%.

The component that may be included in the structure of the present invention in addition to the Y₂O₃—ZrO₂ solid solution includes an oxide such as scandium oxide, europium oxide, gadolinium oxide, erbium oxide, or ytterbium oxide, and a fluoride such as yttrium fluoride or yttrium oxyfluoride. Furthermore, two or more, that is, a plurality of these may be included.

In the present invention, the structure is not limited to a single layer structure, and may be a multilayer structure. A plurality of layers having YZrO of different compositions as main components may be included. A different layer, a layer including Y₂O₃ for example may be provided between the base material and the structure.

### Lattice Constant

According to one embodiment of the present invention, the YZrO constituting the structure is a cubic crystal, with a=b=c, α=β=γ=90°, and its lattice constant is usually 5.212 at a Y₂O₃ content of 40 mol % (ICDD card reference code: 01-081-8080).

In the present invention, the lattice constant is calculated by the following method. X-ray diffraction (XRD) is performed on the structure 20 containing YZrO as a main component on the substrate by θ-2θ scan by out-of-plane measurement. As peaks used for calculating the lattice constant, a peak at a diffraction angle 2θ=29.7° assigned to Miller index (hkl)=(111), a peak at a diffraction angle 2θ=34.4° assigned to Miller index (hkl)=(200), a peak at a diffraction angle 2θ=49.4° assigned to Miller index (hkl)=(220), and a peak at a diffraction angle 2θ=58.7° assigned to Miller index (hkl)=(311) were specified. Since the structure of the present invention is a new structure having a lattice constant a larger than 5.212, the peak positions (2θ) assigned to each Miller index (hlk) actually measured by XRD are shifted to a lower angle side by 0.1 to 0.4° from the theoretical peak positions (2θ) assigned to each Miller index (hkl). In addition, the measurement of the lattice constant is in accordance with JIS K0131.

### Indentation Hardness

According to one embodiment of the present invention, the structure containing YZrO as a main component has an indentation hardness of more than 12 GPa. This improves particle resistance. The indentation hardness is more preferably 13 GPa or more. The upper limit of the indentation hardness is not particularly limited and may be determined depending on the required characteristics, but is, for example, 20 GPa or less.

The indentation hardness of the structure is measured by the following method. The hardness measurement is performed by a microindentation hardness test (nanoindentation) on the surface of the structure containing YZrO as a main component on the substrate. The indenter is a Berkovich indenter, the indentation depth is a fixed value of 200 nm, and the indentation hardness (indentation hardness) H_{IT} is measured. The surface is selected as the measurement point of the H_{IT} on the surface excluding scratches and dents. More preferably, the surface is a polished smooth surface. The number of measurement points is at least 25 points or more. The average value of the H_{IT} measured at 25 points or more is the hardness in the present invention. Other test methods and analysis methods, procedures for verifying the performance of the test device, and conditions required for the standard reference sample are in accordance with ISO14577.

### Etching Rate and Fluoride Content

The composite structure according to the present invention can suppress fluorination in a fluorine plasma environment and also suppress etching by the plasma. More specifically, the Y₂O₃ content of YZrO is preferably in the range from 20 mol % or more to 30 mol % or more to lower the etching rate, and on the other hand, the Y₂O₃ content is preferably in 40 mol % or less to suppress the progress of fluorination.

According to one embodiment of the present invention, after Standard Plasma Test 1 that is described later, a surface roughness Sa (determined according to ISO 25178) of the structure is less than 0.05 μm, preferably less than 0.03 μm. This provides good anti-particle property.

In the present invention, the tests for exposure to fluorine-based plasma defined below will be referred to as Standard Plasma Tests 1 and 2, respectively.

### Plasma Exposure Conditions

For structures containing YZrO as a major component on a substrate, the surface is exposed to a plasma environment using an Inductively Coupled Plasma Reactive Ion Etching (ICP-RIE) apparatus. The plasma environment is formed under the following two conditions.

### Standard Plasma Test 1:

Process gas: SF₆ 100 sccm, Power output: 1500 W of ICP coil output and Bias output: 750 W.

### Standard Plasma Test2:

Process gas: SF₆ 100 sccm, Power output: 1500 W of ICP coil output and Bias output: OFF (0W). Thus, no application to biasing radio frequency power of an electrostatic chuck.

Standard Plasma Tests 1 and 2 are also performed under the common conditions that chamber pressure is 0.5 Pa and that plasma exposure time is one hour. A member for the semiconductor manufacturing apparatus is arranged on a silicon wafer sucked by the electrostatic chuck of the ICP-RIEapparatus to expose the structure surface to the plasma atmosphere formed under such conditions.

### Crystallite Size

According to an embodiment of the present invention, YZrO is polycrystalline. Its average crystallite size is preferably less than 50 nm, more preferably less than 30 nm, and most preferably less than 20 nm. The small average crystallite size allows for smaller particles generated by the plasma.

In this specification, “polycrystal” refers to a structure composed of crystal particles joined and accumulated. It is preferable that the crystalline particles constitute a crystal substantially by themselves. The diameter of the crystal particles is, for example, 5 nanometers (nm) or more.

In the present invention, the crystallite size is measured by, for example, X-ray diffraction. The average crystallite size can be calculated by the Scherrer formula.

### Manufacturing of Composite Structure

The composite structure according to the present invention can be manufactured by a variety of versatile production methods as long as the structure with the above lattice constants can be realized on the base material. That is, it may be manufactured by a method that can form a structure containing YZrO as a main component and having the above-mentioned lattice constant on a base material, such as physical vapor deposition (PVD), chemical vapor deposition (CVD), etc. A structure can be formed on a substrate by. Examples of PVD methods include electron beam physical vapor deposition (EB-PVD), ion beam assisted deposition (IAD), electron beam ion assisted deposition (EB-IAD), ion plating, sputtering, and the like. Examples of CVD methods include thermal CVD, plasma CVD (PECVD), metal organic CVD (MOCVD), mist CVD, laser CVD, and atomic layer deposition (ALD). According to another aspect of the invention, it can be formed by arranging fine particles including a brittle material on a surface of a base material, and applying mechanical impact force on the fine particles. Here, a method of “applying mechanical impact force” includes: using a high-speed rotating brush or roller with high hardness or a piston moving up and down at high speed; using compressive force due to shockwaves produced by explosion; applying ultrasonic waves; or a combination of these.

The composite structure according to the present invention can be preferably manufactured by aerosol deposition (AD method). This “AD method” is a method including the following procedures. Specifically, “aerosol” with the fine particles including the brittle material such as ceramics dispersed in gas is injected toward the base material through a nozzle, to make the fine particles collide with a base material such as metal, glass, ceramics, or plastic at high speed. The fine particles including the brittle material are deformed and crushed through the impact of the collision. As a result, the particles are bonded to each other, whereby a structure (ceramic coat) including a component of the fine particles is formed directly on the base material, to be a layer-shaped structure or a film-shaped structure for example. With this method, no heating means, cooling means, or the like is required in particular, the structure can be formed at a normal temperature, and a structure having a mechanical strength that is equal to or greater than that of a sintered body can be obtained. The density, the mechanical strength, electric property, and the like of the structure can be changed in various ways, by controlling matters such as the condition under which the fine particles collide and the shape and composition of the fine particles. Then, the composite structure according to the present invention can be manufactured by setting various conditions so as to realize the composite structure according to the present invention, that is, to obtain the lattice constant or indentation hardness according to the present invention. For example, the type and flow rate of the carrier gas can be controlled, the particle size of the raw material particles can be adjusted, and further, the various conditions that combine these can be controlled to produce the powder.

The term “fine particles” as used herein refers to particles with an average particle size of 5 micrometers (μm) or less as identified by particle size distribution measurement and scanning electron microscope if the primary particles are dense particles, or to particles with an average particle size of 50 micrometers (μm) or less if the primary particles are porous particles that are easily crushed by the impact.

The term “aerosol” as used herein refers to a solid-air mixed phase material formed by dispersing the fine particles described above in gas (carrier gas) such as helium, nitrogen, argon, oxygen, dry air, or mixed gas including these. The term does cover a case where “aggregates” are included, but preferably refers to a state where fine particles are substantially individually dispersed. The gas pressure and temperature of the aerosol may be set as appropriate based on the physical properties of the desired structure. Still, the concentration of the fine particles in the gas at the point of injection from the discharge port is preferably within a range from 0.0003 mL/L to 5 mL/L, with the gas pressure being 1 atm and the temperature being 20° C.

The process of aerosol deposition is usually executed under a normal temperature, and the structure can be formed at a temperature substantially lower than a melting point of the material of the fine particles, that is, several hundred degrees Celsius or lower. The term “normal temperature” as used herein is a temperature much lower than the sintering temperature of ceramics, and refers to a room temperature environment that is substantially in a range from 0 to 100° C. The term “powder” as used herein refers to a state where the fine particles described above are spontaneously aggregated.

### EXAMPLES

The present invention is further described with reference to the following Examples, but the present invention is not limited to these Examples.

Raw materials Y₂O₃—ZrO₂ solid solution (YZrO) powders for the structures used in the examples were the powder names F-1 to F-7 shown in Table 1 below. The Y₂O₃ content in the YZrO powder was as shown in the table.

In the table, the average particle diameter was measured as follows. A laser diffraction particle size distribution analyzer “LA-960/HORIBA” was used to evaluate the particle size distribution after particles were properly dispersed by ultrasound, and the obtained median diameter D50 was used as the average particle diameter.

As shown in Table 1, a plurality of samples including a structure on a base material was prepared, with a combination between these raw materials and a film formation condition (such as the type and the flowrate of the carrier gas) varied. The low-particle generation of the obtained samples after Standard Plasma Tests 1 and 2 was evaluated. In this example, the samples were prepared by aerosol deposition.

TABLE 1

| | Raw materials | | | | | |
|---|---|---|---|---|---|---|
| | | | Average | Manufacture | | Film |
| | | | particle | conditions | | thick- |
| Sample | Y₂O₃content | Powder | diameter | | Flowrate | ness |
| No | (mol %) | names | (μm) | Gas | (L/min) | (μm) |
| Sample1 | 33 | F-1 | 0.42 | N₂ | 10 L/min | 5.9 |
| Sample2 | 33 | F-1 | 0.42 | He | 10 L/min | 4.5 |
| Sample3 | 40 | F-2 | 0.38 | N₂ | 10 L/min | 7.3 |
| Sample4 | 40 | F-2 | 0.38 | He | 10 L/min | 4.8 |
| Sample5 | 100 | F-3 | 2.04 | He | 10 L/min | 10.1 |

As illustrated in the table, nitrogen gas (N₂) or helium gas (He) is used as the carrier gas. The aerosol was obtained by mixing the carrier gas with material powder (material fine particles) in an aerosol generator. The aerosol thus obtained was injected toward the base material arranged inside a film formation chamber, through a nozzle connected to the aerosol generator, by means of pressure difference. In this process, the air in the film formation chamber has been discharged to the outside by means of a vacuum pump.

### Sample

The structures of Samples 1 to 5 obtained as described above each include a YZrO polycrystalline substance as a main component, with the average crystallite size of the polycrystalline substance being less than 30 nm in any of these.

The crystallite size was measured using XRD. As the XRD apparatus, “Smart Lab available from Rigaku” was used. The XRD measurement conditions were as follows: CuKα (λ=1.5418 Å) used as characteristic X-ray; tube voltage of 45 kV; tube current of 200 mA; Sampling step of 0.01°; and Scan speed of 10.0°/min. As the average crystallite size, the crystallite size was calculated using the Sheller's formula, with the value of K in the Sheller's formula being 0.94.

The main component of the crystal phase of the YZrO on the base material was measured by XRD. As the XRD apparatus, “Smart Lab available from Rigaku” was used. The XRD measurement conditions were as follows: CuKα (A=1.5418 Å) used as characteristic X-ray; tube voltage of 45 kV; tube current of 200 mA; Sampling step of 0.01°; and Scan speed of 10.0°/min. The main component was calculated using XRD analysis software “Smart Lab Studio II available from Rigaku” and the ratio of each crystalline phase was calculated by Rietveld analysis. For the measurement of the main component of the polycrystal in a case of laminated structure, a measurement result for a region at a depth that is less than 1 μm from the outermost surface, obtained by thin film XRD is preferably used.

### Test Evaluation

For samples 1 to 9 obtained as described above, the following lattice constant, indentation hardness, etching rate, arithmetic mean height Sa after plasma irradiation, and fluoride amount were measured. In addition, the Standard Plasma Tests were conducted as follows.

### Measurement of Lattice Constant

The lattice constant of the YZrO solid solution was evaluated by XRD in the following procedure. The XRD device used was “Smart Lab/available from Rigaku”. The XRD measurement conditions were: characteristic X-rays CuKα (λ=1.5418 Å), tube voltage 45 kV, tube current 200 mA, sampling step 0.01°, and scan speed 10.0°/min. The XRD analysis software “SmartLab Studio II/available from Rigaku” was used to identify the obtained XRD diffraction pattern as a cubic crystal of the chemical formula Y2Zr2O7 shown in ICDD card 01-081-8080. Next, the lattice constant was calculated by lattice constant refinement using the external standard method using the XRD analysis software “SmartLab Studio II/available from Rigaku”. Metallic Si was used as the external standard. In addition, as peaks used for calculating the lattice constant, a peak at a diffraction angle 2θ=29.7° assigned to Miller index (hkl)=(111), a peak at a diffraction angle 2θ-34.4° assigned to Miller index (hkl)=(200), a peak at a diffraction angle 2θ-49.4° assigned to Miller index (hkl)=(220), and a peak at a diffraction angle 2θ=58.7° assigned to Miller index (hkl)=(311) were specified. Note that since the structure in the present invention is a new structure having a lattice constant a larger than 5.212, the peak positions (2θ) assigned to each Miller index (hlk) actually measured by XRD are shifted 0.1 to 0.4° toward the lower angle side than the theoretical peak positions (2θ) assigned to each Miller index (hkl). In addition, the measurement of the lattice constant is in accordance with JIS K0131.

### Indentation Hardness Measurement

The indentation hardness of the structure on the substrate was evaluated by the ultra-microindentation hardness test (nanoindentation) in the following procedure. An “ENT-2100/available from Elionix” was used as the ultra-microindentation hardness tester (nanoindenter). The conditions for the ultra-microindentation hardness test were a Berkovich indenter, the test mode was an indentation depth setting test, and the indentation depth was 200 nm. The indentation hardness (indentation hardness) HIT was measured. The measurement points for HIT were set randomly on the surface of the structure, and the number of measurement points was at least 25 points. The average value of the measured HITs at 25 points or more was taken as the hardness.

### Standard Plasma Test

Standard Plasma Tests 1 and 2 under the conditions described above were performed on the samples above, and the low-particle generation after the tests was evaluated through the following procedure. As an ICP-RIE apparatus, “Muc-21 Rv-Aps-Se/available from Sumitomo Precision Products” was used. Standard Plasma Tests 1 and 2 were performed also under the common conditions that chamber pressure is 0.5 Pa and plasma exposure time is one hour. The samples were arranged on the silicon wafer sucked by an electrostatic chuck of the ICP-RIE apparatus to expose the structure surface to the plasma atmosphere formed under such conditions.

### Etching Rate

The etching rate (e) of the structure after Standard Plasma Test 1 was measured using a laser microscope, and a level difference (d) between the non-plasma exposed area and the exposed area was measured using a scanning laser microscope (LEXT OLS-4000, manufactured by Olympus Corporation) and calculated from the plasma exposure time (t) using e=d/t. The plasma non-exposed area was formed by partially masking the surface of the structure with a polyimide film before the Standard Plasma Test 1.

Arithmetic Mean Height Sa after Plasma Irradiation

Regarding the surface roughness of the structure after Standard Plasma Test 1, Sa (arithmetic mean height) defined in ISO25178 was evaluated using a laser microscope. The laser microscope used was “OLS4500/manufactured by Olympus Corporation.” The objective lens used was MPLAPON 100XLEXT, and the cutoff value λc was set to 25 μm.

### Fluoride Amount

The surface of the structure after Standard Plasma Test 2 was analyzed using X-ray photoelectron spectroscopy (XPS) in the depth direction using ion sputtering; at every interval, the atomic concentration (%) of fluorine (F) atoms was measured. “K-Alpha/manufactured by Thermo Fisher Scientific” was used as the XPS device. All the obtained atomic concentrations (%) of fluorine (F) atoms every second from 5 seconds to 149 seconds of sputtering time were integrated, and this was taken as the integrated amount of fluoride (%) on the surface of the structure. In addition, in order to eliminate the influence of carbon (C) adhering to the surface layer as contamination, data for sputtering times of 0 seconds to 5 seconds were not included.

The test results are as shown in the table below.

TABLE 2

| | | | | Arithmetic | Fluoride |
|---|---|---|---|---|---|
| | Lattice | Indentation | Etching | mean height | amount |
| Sample | constant | hardness | rate | Sa after plasma | (at |
| No | (Å) | (GPa) | (μm/hr) | irradiation (μm) | %@145 s) |
| Sample 1 | 5.217 | 11.0 | 2.1 | 0.09 | 2363 |
| Sample 2 | 5.270 | 14.8 | 1.9 | 0.02 | 1011 |
| Sample 3 | 5.252 | 11.8 | 1.8 | 0.05 | 2264 |
| Sample 4 | 5.272 | 14.1 | 1.8 | 0.02 | 954 |
| Sample5 | — | 11.4 | 1.1 | 0.02 | 1316 |

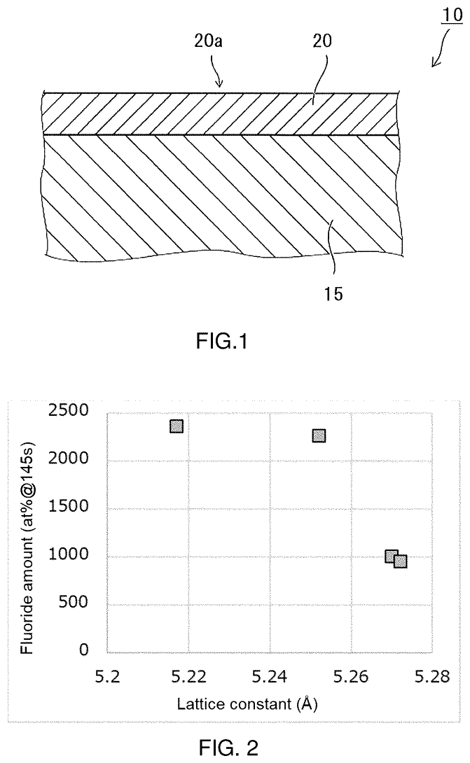

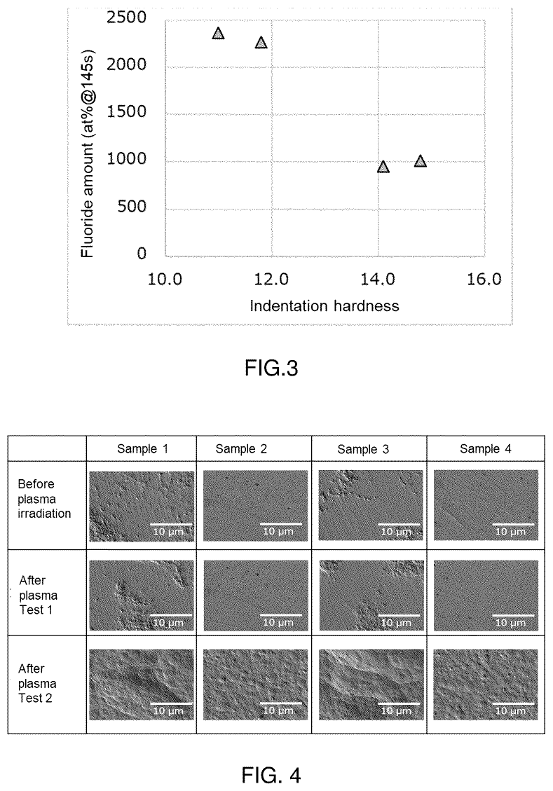

The relation between the lattice constant value and the Y₂O₃ content is shown in FIG. 2. The relationship between the indentation hardness and the Y₂O₃ content is shown in a graph in FIG. 3.

### SEM Image

SEM images of the surface of the structure after Standard Plasma Tests 1 and 2 were taken as follows. A scanning electron microscope (SEM) was used to evaluate the corrosion state of the plasma-exposed surface. The SEM used was “SU-8220/manufactured by Hitachi, Ltd.” The acceleration voltage was 3 kV. The resulting photographs are shown in FIG. 4.

The embodiments of the present invention are described above. However, the present invention is not limited to the description thereof. Modes as a result of design change on the embodiments described above by a person skilled in the art are also included in the scope of the present invention as long as the modes have the features of the present invention. For example, the shape, dimension, material, arrangement, of the structure or the base material are not limited to those exemplified, and can be changed as appropriate. The elements of the embodiments described above can be combined as long as such combinations are technically reasonable. The combinations are included in the scope of the present invention as long as the combinations have the features of the present invention.

1. A composite structure comprising: a base material; and a structure provided on the base material and has a surface,
wherein the structure comprises Y₂O₃—ZrO₂ solid solution (YZrO) as a main component, and lattice constant of the YZrO is 5.252 Å or greater.

2. The composite structure according to claim 1, wherein the lattice constant of the YZrO is 5.270 Å or greater.

3. A composite structure comprising: a base material; and a structure provided on the base material and has a surface,
wherein the structure comprises Y₂O₃—ZrO₂ solid solution (YZrO) as a main component, and has an indentation hardness of more than 12 GPa.

4. The composite structure according to claim 3, wherein the indentation hardness of more than 13 GPa.

5. The composite structure according to claim 1, wherein after Standard Plasma Test 1, a surface roughness Sa (determined according to ISO 25178) of the structure is less than 0.05 μm.

6. The composite structure according to claim 5, wherein after Standard Plasma Test 1, the surface roughness Sa (determined according to ISO 25178) of the structure is less than 0.03 μm.

7. The composite structure according to claim 1, wherein the Y₂O₃ content is in the range from 20 mol % or more to 40 mol % or less.

8. The composite structure according to claim 1, wherein the Y₂O₃ content is in the range from 30 mol % or more to 40 mol % or less.

9. The composite structure according to claim 1, wherein the structure consisting of Y₂O₃—ZrO₂ solid solution (YZrO).

10. The composite structure according to claim 1, wherein an average crystallite size of the structure is less than 50 nm.

11. The composite structure according to claim 1 used in an environment requiring low-particle generation.

12. The composite structure according to claim 11 that is a member for a semiconductor manufacturing apparatus.

13. (canceled)

14. The composite structure according to claim 3, wherein after Standard Plasma Test 1, a surface roughness Sa (determined according to ISO 25178) of the structure is less than 0.05 μm.

15. The composite structure according to claim 14, wherein after Standard Plasma Test 1, the surface roughness Sa (determined according to ISO 25178) of the structure is less than 0.03 μm.

16. The composite structure according to claim 3, wherein the Y₂O₃ content is in the range from 20 mol % or more to 40 mol % or less.

17. The composite structure according to claim 3, wherein the Y₂O₃ content is in the range from 30 mol % or more to 40 mol % or less.

18. The composite structure according to claim 3, wherein the structure consisting of Y₂O₃—ZrO₂ solid solution (YZrO).

19. The composite structure according to claim 3, wherein an average crystallite size of the structure is less than 50 nm.

20. The composite structure according to claim 3 used in an environment requiring low-particle generation.

21. The composite structure according to claim 20 that is a member for a semiconductor manufacturing apparatus.
